(19) United States
(12) Patent Application Publication
(10) Pub. No.: US 2024/0146055 A1
(43) Pub. Date: May 2, 2024

(54) POWER RECEIVING AND DISTRIBUTING EQUIPMENT MANAGEMENT DEVICE, POWER RECEIVING AND DISTRIBUTING EQUIPMENT MANAGEMENT METHOD, AND COMPUTER READABLE MEDIUM STORING PROGRAM

(71) Applicant: Mitsubishi Electric Corporation, Tokyo (JP)

(72) Inventors: Yoshitsugu KAWAMURA, Tokyo (JP); Yuki KAWASHIMA, Tokyo (JP); Takahisa YAMAUCHI, Tokyo (JP)

(73) Assignee: Mitsubishi Electric Corporation, Tokyo (JP)

(21) Appl. No.: 18/409,539

(22) Filed: Jan. 10, 2024

Related U.S. Application Data
(63) Continuation of application No. PCT/JP2021/032941, filed on Sep. 8, 2021.

(51) Int. Cl. H02J 3/00; G01R 19/25

(52) U.S. Cl. CPC H02J 3/001; G01R 19/2513

(57) ABSTRACT

Because power receiving and distributing equipment is configured with a plurality of devices combined together, it is sometimes difficult to perform inspection operation for the inspection items separated into those set for each individual device. Therefore, in the power receiving and distributing equipment, even if an attempt is made to associate each device with an inspection result, an inspection result of a plurality of devices that are grouped cannot be associated with each device. According to the present disclosure, an inspection result of the power receiving and distributing equipment can be associated with an inspection item of each device.

### CROSS REFERENCE TO RELATED APPLICATION

This application is a Continuation of PCT International Application No. PCT/JP2021/032941, filed on Sep. 8, 2021, which is hereby expressly incorporated by reference into the present application.

### TECHNICAL FIELD

The present disclosure relates to a power receiving and distributing equipment management device, a power receiving and distributing equipment management system, and a power receiving and distributing equipment management method for managing a plurality of devices arranged in power receiving and distributing equipment.

### BACKGROUND ART

A facility that uses a large amount of electricity at a time, such as a building or a factory, is equipped with power receiving and distributing equipment that converts high-voltage electricity sent from a power plant into low-voltage electricity in the facility and distributes the low-voltage electricity to devices in the facility. The power receiving and distributing equipment includes various devices such as a circuit breaker, a transformer, and a measurement device to transform and distribute the high-voltage electricity. When inspecting such power receiving and distributing equipment, an operator goes to a site where the power receiving and distributing equipment is installed, checks inspection items set for each device, for example, the appearance, abnormal smell, and temperature of the device, and records the results as inspection results.

### PRIOR ART DOCUMENT

### Patent Document

Patent Document 1: Japanese Unexamined Patent Publication No. H8-019178

### SUMMARY OF INVENTION

### Problems to be Solved by Invention

As a device that supports such maintenance, Patent Document 1 discloses a power system equipment maintenance support device that associates individual components of a power system with their patrol and inspection data and displays them. However, because the power receiving and distributing equipment is configured with a plurality of devices combined together, it is sometimes difficult to perform inspection operation for the inspection items separated into those set for each individual device. For example, in a case where there is an inspection item of the same “presence or absence of abnormal smell” for a plurality of devices, the operator cannot distinguish the abnormal smell from each device, thus checks the presence or absence of the abnormal smell around a plurality of devices that are grouped, and records one inspection result for the plurality of devices that are grouped. Therefore, in the power receiving and distributing equipment, even if an attempt is made to associate each device with an inspection result as in the power system equipment maintenance support device described in Patent Document 1, an inspection result of a plurality of devices that are grouped cannot be associated with each device.

The present disclosure is made to solve the above-described problem and to obtain a power receiving and distributing equipment management device that associates an inspection result of the power receiving and distributing equipment with an inspection item of each device.

### Means for Solving Problems

A power receiving and distributing equipment management device according to the present disclosure comprises: an individual inspection item acquisition unit to acquire individual inspection items corresponding to a plurality of devices arranged in equipment; an integrated inspection item generation unit to extract an inspection item common to some of the plurality of devices as a common inspection item from among the individual inspection items acquired by the individual inspection item acquisition unit, and generate integrated inspection items by integrating the extracted common inspection item and one or more of the individual inspection items; an acquisition unit to acquire integrated inspection results corresponding to the integrated inspection items generated by the integrated inspection item generation unit; and a recording unit to record the integrated inspection results acquired by the acquisition unit in association with the individual inspection items corresponding to the integrated inspection items.

### Effects of Invention

According to the present disclosure, an inspection result of the power receiving and distributing equipment can be associated with an inspection item of each device.

### BRIEF DESCRIPTION OF DRAWINGS

FIG. 1 is a configuration diagram showing a configuration of a power receiving and distributing equipment management device according to Embodiment 1.

FIG. 2 is an explanatory diagram showing a configuration of individual inspection items acquired by an individual inspection item acquisition unit of the power receiving and distributing equipment management device according to Embodiment 1.

FIG. 3 is an explanatory diagram showing a configuration of integrated inspection items generated by an integrated inspection item generation unit of the power receiving and distributing equipment management device according to Embodiment 1.

FIG. 4 is an explanatory diagram showing a configuration of integrated inspection results acquired by an acquisition unit of the power receiving and distributing equipment management device according to Embodiment 1.

FIG. 5 is an explanatory diagram of inspection results corresponding to individual inspection items recorded by a recording unit of the power receiving and distributing equipment management device according to Embodiment 1.

FIG. 6 is a flowchart showing an operation of the power receiving and distributing equipment management device according to Embodiment 1.

FIG. 7 is an explanatory diagram showing that association with information on a device A is performed through a single-line diagram DB and an inspection result DB by the power receiving and distributing equipment management device according to Embodiment 1.

FIG. 8 is a hardware configuration diagram of the power receiving and distributing equipment management device according to a present embodiment.

### MODE FOR CARRYING OUT INVENTION

### Embodiment 1

A power receiving and distributing equipment management device 100 according to Embodiment 1 will be described below. The power receiving and distributing equipment management device 100 is a device for managing inspection results of a plurality of devices arranged in equipment such as power receiving and distributing equipment. The plurality of devices are those that make up the power receiving and distributing equipment, such as a section switch, a disconnector, a load switch, a circuit breaker, a transformer, a protective relay, a control device, a measurement device, and a molded case circuit breaker. For the sake of simplicity, the present embodiment describes a case where inspections are performed on three devices arranged in the equipment, i.e., the circuit breaker, the transformer, and the measurement device.

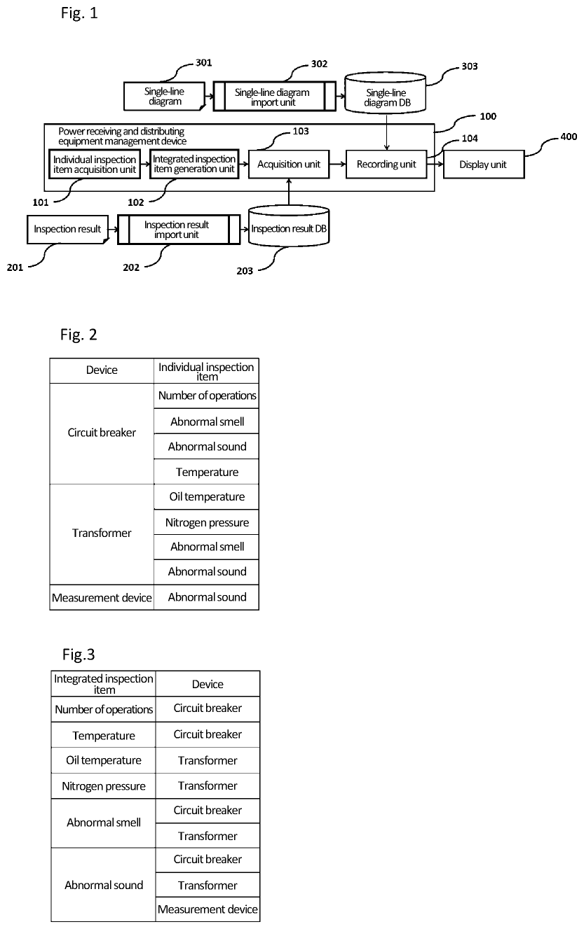

FIG. 1 is a configuration diagram showing a configuration of the power receiving and distributing equipment management device 100 according to Embodiment 1. An inspection result from an inspection result DB 203 and a single-line diagram from a single-line diagram DB 303 are inputted to the power receiving and distributing equipment management device 100, and these information items are associated with individual devices and outputted to a display unit 400. The power receiving and distributing equipment management device 100 includes: an individual inspection item acquisition unit 101 to acquire individual inspection items corresponding to a plurality of devices arranged in the equipment; an integrated inspection item generation unit 102 to extract an inspection item common to some of the plurality of devices as a common inspection item from among the individual inspection items acquired by the individual inspection item acquisition unit 101, and generate integrated inspection items by integrating the extracted common inspection item and one or more of the individual inspection items; an acquisition unit 103 to acquire integrated inspection results corresponding to the integrated inspection items generated by the integrated inspection item generation unit 102; and a recording unit 104 to record the integrated inspection results acquired by the acquisition unit 103 in association with the individual inspection items corresponding to the integrated inspection items.

The individual inspection item acquisition unit 101 acquires individual inspection items corresponding to the plurality of devices arranged in the equipment. The individual inspection items are inspection items set for each device; for example, in a case of a circuit breaker, there are items such as the number of operations, grounding, overheating, and discoloration; in a case of a transformer, there are items such as oil temperature, nitrogen pressure, oil level, leakage, and corrosion sound. In the description of the present embodiment, the following individual inspection items as shown in FIG. 2 are assumed; for the circuit breaker, the number of operations, abnormal smell, abnormal sound, and temperature; for the transformer, oil temperature, nitrogen pressure, abnormal smell, and abnormal sound; and for the measurement device, abnormal sound. These individual inspection items may be data of inspection items corresponding to the plurality of devices, and they are inputted by a user, for example.

The integrated inspection item generation unit 102 extracts an inspection item common to some of the plurality of devices as a common inspection item from among the individual inspection items acquired by the individual inspection item acquisition unit 101, and generates integrated inspection items by integrating the extracted common inspection item and one or more of the individual inspection items. The common inspection item is an inspection item common to two or more devices among the individual inspection items acquired by the individual inspection item acquisition unit 101. The “common” item refers to an item to be collectively inspected for a plurality of devices among the individual inspection items. For example, as described above, it is an item for which an operator makes a determination of a collective inspection result for the plurality of devices when inspecting for the presence or absence of abnormal smell because it is difficult to make a determination for an individual device. Regarding a method for extracting the common inspection item, the common inspection item may be extracted by extracting an individual inspection item common to some of the plurality of devices, or by extracting a common inspection item by the user. When there are individual inspection items as shown in FIG. 2, the abnormal smell is a common inspection item common to the circuit breaker and the transformer, and the abnormal sound is a common inspection item common to the circuit breaker, the transformer, and the measurement device.

The integrated inspection item generation unit 102 generates the integrated inspection items by integrating the common inspection items and the individual inspection items. Specifically, among the individual inspection items, items not extracted as the common inspection items and items extracted as the common inspection items are defined as the integrated inspection items. FIG. 3 is an explanatory diagram showing a configuration of the integrated inspection items generated by the integrated inspection item generation unit 102 of the power receiving and distributing equipment management device 100 according to Embodiment 1. The integrated inspection items are the number of operations, the temperature, the oil temperature, the nitrogen pressure, the abnormal smell, and the abnormal sound, which are the integrated inspection items indicating the inspection items of the entire equipment. Here, the common inspection items may be associated with the devices corresponding to the individual inspection items. FIG. 3 shows that the integrated inspection items are also associated with respective devices; the number of operations and the temperature are associated with the circuit breaker; the oil temperature and the nitrogen pressure are associated with the transformer; the abnormal smell is associated with the circuit breaker and the transformer; and the abnormal sound is associated with the circuit breaker, the transformer, and the measurement device. The operator inspects the equipment for these integrated inspection items.

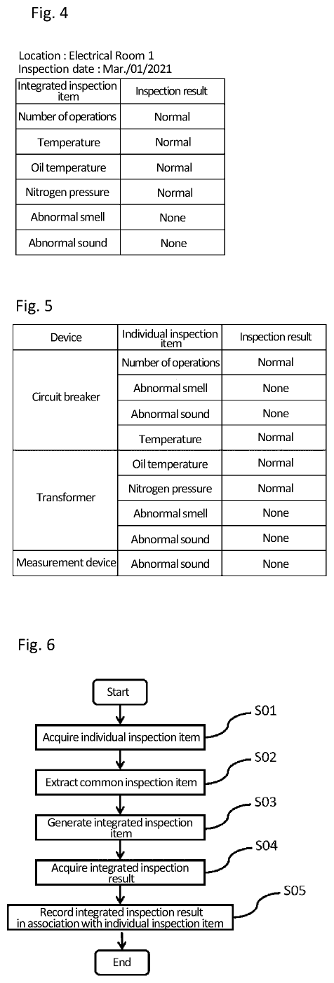

The acquisition unit 103 acquires integrated inspection results corresponding to the integrated inspection items generated by the integrated inspection item generation unit 102. The acquisition unit 103 acquires the integrated inspection results from the inspection result DB 203. The operator who inspects the equipment inspects the integrated inspection items when inspecting the equipment, and acquires inspection results 201 corresponding to the integrated inspection items. FIG. 4 is an explanatory diagram showing a configuration of the inspection results acquired by the acquisition unit 103 of the power receiving and distributing equipment management device according to Embodiment 1. FIG. 4 shows, with respect to the integrated inspection results, that the number of operations is normal, the temperature is normal, the oil temperature is normal, the nitrogen pressure is normal, there is no abnormal smell, and there is no abnormal sound. Although the number of operations, the temperature, the oil temperature, and the nitrogen pressure are described as “normal”, specific numerical values may be described here, and the contents of the inspection results may be any contents as long as the inspection results can be understood for the inspection items. Further, the inspection results may include a location and an inspection date. In the inspection results shown in FIG. 4, it is described that the location is Electrical Room 1 and the inspection date is Mar. 1, 2021. The inspection results 201 are electronic data such as PDF, JPG, CAD, etc., or information such as a PDF version of the paper with the inspection results written on it. The inspection results are converted into a format that can be stored in the inspection result DB 203 by an inspection result import unit 202, and are stored in the inspection result DB 203 together with the information of the inspection location and the inspection date. The acquisition unit 103 accesses the inspection result DB as necessary to acquire information on the inspection results which are the integrated inspection results.

The recording unit 104 records the integrated inspection results acquired by the acquisition unit 103 in association with the individual inspection items corresponding to the integrated inspection items. The recording unit 104 records the integrated inspection results in association with the devices that are associated with the integrated inspection items when the integrated inspection item generation unit 102 generates the integrated inspection items. As shown in FIG. 3, the integrated inspection items are associated with the devices on the basis of the common inspection items and the individual inspection items from which the integrated inspection items are integrated. With reference to these, the integrated inspection results are recorded in association with the individual inspection items. FIG. 5 is an explanatory diagram of the inspection results corresponding to the individual inspection items recorded by the recording unit 104 of the power receiving and distributing equipment management device 100 according to Embodiment 1. From the integrated inspection results, the following inspection results are correspondingly recorded: for the circuit breaker, the number of operations is normal, there is no abnormal smell, there is no abnormal sound, and the temperature is normal; for the transformer, the oil temperature is normal, the nitrogen pressure is normal, there is no abnormal smell, there is no abnormal sound; and for the measurement device, there is no abnormal sound.

Note that, it is described that the recording unit 104 performs association with the devices that are associated with the integrated inspection items when the integrated inspection items are generated; however, the integrated inspection items and the individual inspection items may be compared with each other, and the same inspection result may be associated with the same inspection item, and it suffices that the association with the individual inspection items may be performed from the integrated inspection items corresponding to the integrated inspection results.

Further, a single-line diagram is inputted to the recording unit 104. A single-line diagram 301 is a connection diagram in which the electrical system of the devices of the equipment is indicated by a single line. The format of the diagram is electronic data such as PDF, JPG, and CAD, or information such as a PDF created by scanning a diagram printed on paper. The single-line diagram 301 is converted into a format that can be stored in the single-line diagram DB 303 by a single-line diagram import unit 302 and recorded in the single-line diagram DB 303. The recording unit 104 associates the devices corresponding to the individual inspection items with the corresponding devices in the single-line diagram. The association with the devices may be performed by the user or may be automatically performed by machine learning. Although the information of the single-line diagram is used this time, other information may be used as long as it includes information on the equipment or information that indicates the relationship between the devices arranged in the equipment. For example, the equipment information includes information such as physical sizes, rated voltages, allowable currents, set values, position information, and communication addresses of the devices. The information that indicates the relationship between the devices arranged in the equipment includes a physical inclusion relationship, an electrical connection relationship, and a relationship by communication lines.

The display unit 400 receives information to be displayed from the recording unit 104 of the power receiving and distributing equipment management device 100 in response to a request from the user. For example, when receiving a request to display a single-line diagram from the operator, the display unit 400 receives the single-line diagram from the single-line diagram DB 303 through the power receiving and distributing equipment management device 100 and displays it. When the operator selects a device on the single-line diagram, an inspection result is received from the inspection result DB 203 through the power receiving and distributing equipment management device 100, and the inspection result is displayed. At this time, because association with the inspection result is performed by the power receiving and distributing equipment management device 100, only the inspection result related to the selected device can be displayed. When an inspection date is included in the inspection result, the user can designate and display a desired inspection date from inspection results stored in the inspection result DB.

Next, an operation of the power receiving and distributing equipment management device according to Embodiment 1 will be described. FIG. 6 is a flowchart showing the operation of the power receiving and distributing equipment management device 100 according to Embodiment 1.

First, in step S01, the individual inspection item acquisition unit 101 acquires individual inspection items corresponding to the plurality of devices arranged in the equipment. In the present embodiment, there are following individual inspection items as shown in FIG. 2; for the circuit breaker, the number of operations, the abnormal smell, the abnormal sound, and the temperature; for the transformer, the oil temperature, the nitrogen pressure, the abnormal smell, and the abnormal sound; and for the measurement device, the abnormal sound.

Next, in step S02, the integrated inspection item generation unit 102 extracts an inspection item common to some of the plurality of devices as a common inspection item from among the individual inspection items acquired by the individual inspection item acquisition unit 101. Specifically, an individual inspection item common to some of the plurality of devices is extracted as a common inspection item. In FIG. 2, the abnormal smell is a common inspection item common to the circuit breaker and the transformer, and the abnormal sound is a common inspection item common to the circuit breaker, the transformer, and the measurement device.

In step S03, the integrated inspection item generation unit 102 generates the integrated inspection items by integrating the common inspection items and the individual inspection items such that the item contents of the common inspection items and the individual inspection items do not overlap. Specifically, among the individual inspection items, items that are not the common inspection items and items that are the common inspection items are defined as the integrated inspection items. As shown in FIG. 3, the integrated inspection items are the number of operations, the temperature, the oil temperature, the nitrogen pressure, the abnormal smell, and the abnormal sound, which are the integrated inspection items indicating the inspection items of the entire equipment. Further, the common inspection items are associated with the devices corresponding to the individual inspection items; also for the integrated inspection items, the number of operations and the temperature are associated with the circuit breaker; the oil temperature and the nitrogen pressure are associated with the transformer; the abnormal smell is associated with the circuit breaker and the transformer; and the abnormal sound is associated with the circuit breaker, the transformer, and the measurement device. By this step, items to be inspected for the entire equipment can be put together. If the operator inspects the integrated inspection items, it means that the operator has inspected the entire equipment.

In step S04, the acquisition unit 103 acquires integrated inspection results corresponding to the integrated inspection items generated by the integrated inspection item generation unit 102. Specifically, as shown in FIG. 4, the acquisition unit 103 acquires, from the inspection result DB 203, the integrated inspection results in which the number of operations is normal, the temperature is normal, the oil temperature is normal, the nitrogen pressure is normal, there is no abnormal smell, and there is no abnormal sound.

In step S05, the recording unit 104 records the integrated inspection results acquired by the acquisition unit 103 in association with the individual inspection items corresponding to the integrated inspection items. The recording unit 104 records the integrated inspection results in association with the devices that are associated with the integrated inspection items when the integrated inspection item generation unit generates the integrated inspection items. The integrated inspection items are associated with the devices on the basis of the common inspection items and the individual inspection items from which the integrated inspection items are integrated. With reference to these, an inspection result for each individual inspection item of each device as shown in FIG. 5 is recorded. From the integrated inspection results, the following inspection results are correspondingly recorded: for the circuit breaker, the number of operations is normal, there is no abnormal smell, there is no abnormal sound, and the temperature is normal; for the transformer, the oil temperature is normal, the nitrogen pressure is normal, there is no abnormal smell, there is no abnormal sound; and for the measurement device, there is no abnormal sound.

In this way, the power receiving and distributing equipment management device 100 can record the integrated inspection results including the inspection results of a plurality of devices that are grouped in association with the inspection results of the individual inspection items, which are the inspection items of the respective devices. Thus, for example, in a case where the user wants to obtain a past inspection result regarding one device, only the inspection result corresponding to the device can be easily extracted with the power receiving and distributing equipment management device 100. Therefore, when the operator of the equipment investigates the cause of a failure, the information on the individual device can be quickly obtained, and the time for the failure analysis can be shortened.

As described above, according to the power receiving and distributing equipment management device 100 of Embodiment 1, because the integrated inspection results including the inspection results integrated for the plurality of devices are recorded in association with the individual inspection items for the respective devices, the inspection results of the power receiving and distributing equipment can be associated with the inspection items of the respective devices.

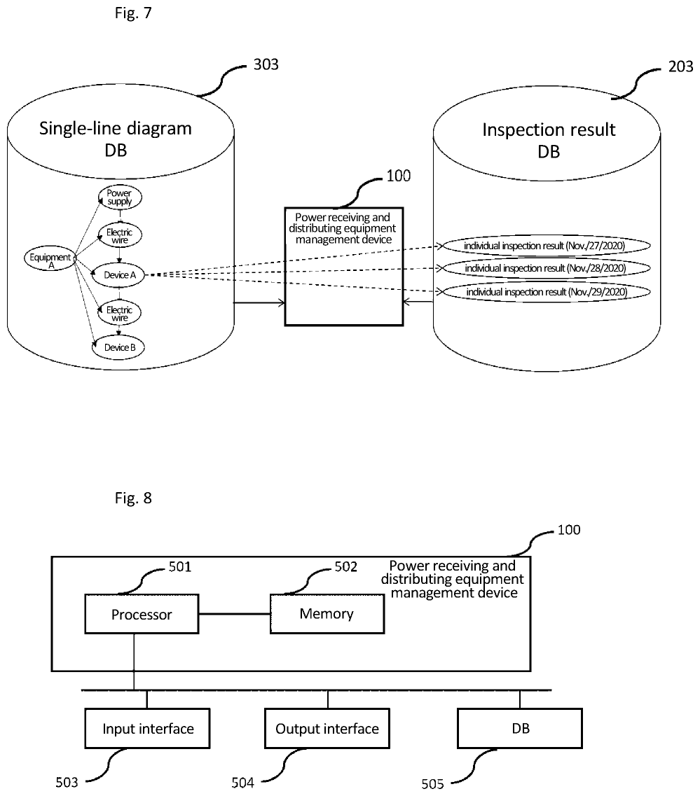

Note that, each time the operator performs inspections corresponding to the integrated inspection items for the equipment, the inspection results may be accumulated in the inspection result DB 203. FIG. 7 is an explanatory diagram showing that association with information on a device A is performed through the single-line diagram DB and the inspection result DB by the power receiving and distributing equipment management device according to Embodiment 1. In the single-line diagram DB 303, information on the relationships regarding equipment A between a power supply, an electric wire, the device A, an electric wire, and a device B is recorded. In the inspection result DB 203, three inspection results with different inspection dates are accumulated. For example, the device A on the single-line diagram is associated with the three individual inspection results regarding the device A by the power receiving and distributing equipment management device 100. Therefore, when the user selects the device A on the single-line diagram displayed on the display unit, the three individual inspection results with different inspection dates regarding the device A can be displayed.

The above-described embodiment is implemented by a hardware configuration diagram shown in FIG. 8. FIG. 8 is a configuration diagram in a case where it is realized by hardware. The individual inspection item acquisition unit 101, the integrated inspection item generation unit 102, the acquisition unit 103, and the recording unit 104 of the power receiving and distributing equipment management device 100 are executed by a processor 501, which is a computing device, and their computing results are stored in a memory 502 as necessary. An inspection result, a single-line diagram, selection of an inspection item, and the like are inputted by an input interface 503, which is an input device. The output to be displayed on the display unit 400 is outputted by an output interface 504, which is an output device. The inspection results and the single-line diagram are stored in a database 505. Note that the processing of the computing device may be realized as electric circuitry.

### DESCRIPTION OF REFERENCE NUMERALS

100. power receiving and distributing equipment management device
101. individual inspection item acquisition unit
102. integrated inspection item generation unit
103. acquisition unit
104. recording unit
201. inspection result
202. inspection result import unit
203. inspection result DB
301. single-line diagram
302. single-line diagram import unit
303. single-line diagram DB
400. display unit
501. processor
502. memory
503. input interface
504. output interface
505. database

1. A power receiving and distributing equipment management device comprising processing circuitry
to acquire individual inspection items corresponding to a plurality of devices arranged in equipment,
to extract an inspection item common to some of the plurality of devices as a common inspection item from among the acquired individual inspection items, and generate integrated inspection items by integrating the extracted common inspection item and one or more of the individual inspection items,
to acquire integrated inspection results corresponding to the generated integrated inspection items, and
to record the acquired integrated inspection results in association with the individual inspection items corresponding to the integrated inspection items.

2. The power receiving and distributing equipment management device according to claim 1, wherein
the processing circuitry acquires information indicating relationships between the devices in the equipment, and associates the devices in the acquired information with the devices corresponding to the individual inspection items.

3. The power receiving and distributing equipment management device according to claim 2, wherein
the processing circuitry uses machine learning to associate the devices in the acquired information with the devices corresponding to the individual inspection items.

4. A power receiving and distributing equipment management method comprising:
acquiring individual inspection items corresponding to a plurality of devices arranged in equipment;
extracting an inspection item common to some of the plurality of devices as a common inspection item from among the acquired individual inspection items, and generating integrated inspection items by integrating the extracted common inspection item and one or more of the individual inspection items;
acquiring integrated inspection results corresponding to the generated integrated inspection items; and
recording the acquired integrated inspection results in association with the individual inspection items corresponding to the integrated inspection items.

5. A non-transitory computer-readable medium storing a power receiving and distributing equipment management program for performing processes of
acquiring individual inspection items corresponding to a plurality of devices arranged in equipment,
extracting an inspection item common to some of the plurality of devices as a common inspection item from among the acquired individual inspection items, and generating integrated inspection items by integrating the extracted common inspection item and one or more of the individual inspection items,
acquiring integrated inspection results corresponding to the generated integrated inspection items, and
recording the acquired integrated inspection results in association with the individual inspection items corresponding to the integrated inspection items.
